(19) United States
(12) Patent Application Publication
(10) Pub. No.: US 2011/0215452 A1
(43) Pub. Date: Sep. 8, 2011

(54) SEMICONDUCTOR PACKAGE, SUBSTRATE, ELECTRONIC COMPONENT, AND METHOD OF MOUNTING SEMICONDUCTOR PACKAGE

(75) Inventor: Naoki SAKURA, Kanagawa (JP)

(73) Assignee: RENESAS ELECTRONICS CORPORATION, Kanagawa (JP)

(21) Appl. No.: 13/042,009

(22) Filed: Mar. 7, 2011

(30) Foreign Application Priority Data
Mar. 8, 2010 (JP) 2010-051071

(51) Int. Cl. H01L 23/495; H01L 21/60; H05K 1/11

(52) U.S. Cl. 257/666; 438/123; 174/262; 257/E21.506; 257/E23.031; 257/E29.242; 257/E29.173

(57) ABSTRACT

A semiconductor package includes a semiconductor device and a substrate over which the semiconductor device is mounted, wherein the substrate includes: an internal ground electrode, formed in the one side of the substrate, which is connected to the semiconductor device; two external ground electrodes, located at the opposite side of the substrate opposite to the one side of the substrate, which are electrically connected to the internal ground electrode; at least one sub-ground electrode, located between the two external ground electrodes, when seen in a plan view, and located at the opposite side of the substrate, which is electrically connected to the internal ground electrode; an internal input electrode, formed in the one side of the substrate, which is connected to the semiconductor device; and an internal output electrode, formed in the one of the substrate, which is connected to the semiconductor device.

This application is based on Japanese patent application No. 2010-051071, the content of which is incorporated hereinto by reference.

### BACKGROUND

1. Technical Field

The present invention relates to a semiconductor package having a sub-ground electrode that connects an internal ground electrode to the outside, a substrate, an electronic component, and a method of mounting the semiconductor package.

2. Related Art

As packages used in a discrete transistor for small-signal low-noise amplification in a high-frequency band, there are a resin sealing package, a resin package having a hollow structure, and a ceramic package having a hollow structure. On the other hand, the packages used in the high-frequency band require the suppression of lowering of a gain in the high-frequency band, the reduction in parasitic capacitance, ensuring of air-tightness, low costs and the like. There are techniques disclosed in Japanese Patent Nos. 3,125,868 and 2,638,514, and Japanese Unexamined Patent Publication Nos. 5-218231, 2-17664 and 2001-44328 for the purpose of solving these problems.

Japanese Patent No. 3,125,868 discloses a technique for suppressing the deterioration of air-tightness in the semiconductor package by the generation of a gap in the interface between a mold portion and a metal lead portion due to the difference in coefficients of thermal expansion. Specifically, the technique is disclosed for covering the interface between the metal lead portion and the mold portion with a nonconductive film. In addition, Japanese Patent No. 2,638,514 discloses a technique for suppressing the lowering of a gain in the high-frequency band by increasing the earth capacity at the output side.

Japanese Unexamined Patent Publication No. 5-218231 discloses a technique for suppressing parasitic capacitance in the connection portion of an inner lead and an outer lead to a small level and thus improving the high-frequency characteristics. Japanese Unexamined Patent Publication No. 2-17664 discloses a technique for obtaining the required characteristics in use of the high-frequency band, even while a low-cost resin mold material is used as a package material. Japanese Unexamined Patent Publication No. 2001-44328 discloses a technique for forming a stable ground network in a ground conducting layer and a through conducting layer, and effectively accurately propagating a high-speed signal.

### SUMMARY

When a portion of an output is returned to an input in an amplifier circuit, matching of both phases thereof brings a positive feedback, which results in an increase in the gain. On the other hand, in the case of the positive feedback, a stable coefficient or a noise figure of the amplifier circuit is degraded. Therefore, the amount of positive feedback should be adjusted in order to set a gain, a stable coefficient and a noise figure to proper values. In Japanese Patent Nos. 3,125,868 and 2,638,514, and Japanese Unexamined Patent Publication Nos. 5-218231, 2-17664 and 2001-44328, it is necessary to redesign the semiconductor package structures in order to change the amount of positive feedback.

In one embodiment, there is provided a semiconductor package including: a semiconductor device; and a substrate over which the semiconductor device is mounted, wherein the substrate includes: an internal ground electrode, formed in the one side of the substrate, which is connected to the semiconductor device; two external ground electrodes, located at the opposite side of the substrate opposite to the one side of the substrate, which are electrically connected to the internal ground electrode; at least one sub-ground electrode, located between the two external ground electrodes, when seen in a plan view, and located at the opposite side of the substrate, which is electrically connected to the internal ground electrode; an internal input electrode, formed in the one side of the substrate, which is connected to the semiconductor device; and an internal output electrode, formed in the one side of the substrate, which is connected to the semiconductor device.

Since a feedback path from an output to an input passes through the internal ground electrode in its halfway point, the feedback path is grounded through an inductance element located between the internal ground electrode and the external ground electrode. Therefore, when the inductance element value of such a grounding path is brought close to zero, the feedback path is short-circuited along the way, and the amount of the feedback decreases. In addition, when the inductance element value of the grounding path is made larger, the amount of the feedback increases.

According to the invention, two external ground electrodes that connect the internal ground electrode to the outside are provided in the substrate. In addition, a plurality of sub-ground electrodes that connects the internal ground electrode to the outside is provided between the two external ground electrodes. Thereby, the grounding path becomes a path through the sub-ground electrode closer to the transistor than the external ground electrode. Therefore, the grounding path is shortened, and the inductance element value of the grounding path is reduced.

Further, it is possible to select the grounding path by changing the pattern of the ground interconnect in the mounting substrate and selecting the sub-ground electrode to be connected. Thereby, the inductance element value of the grounding path can be made variable. Therefore, it is possible to control the amount of the positive feedback without changing the structure of the semiconductor package, and to perform the design of electronic components including the values of the gain, the stable coefficient and the noise figure.

In another embodiment, there is provided a substrate including: an internal ground electrode formed in the one side of the substrate; two external ground electrodes, located at the opposite side of the substrate opposite to the one side of the substrate, which are electrically connected to the internal ground electrode; at least one sub-ground electrode, located between the two external ground electrodes, when seen in a plan view, and located at the opposite side of the substrate, which is electrically connected to the internal ground electrode; an internal input electrode formed in the one side of the substrate; and an internal output electrode formed in the one side of the substrate.

In still another embodiment, there is provided an electronic component including: a mounting substrate;

and a semiconductor package mounted over the mounting substrate, wherein the semiconductor package includes: a semiconductor device; and a substrate over which the semiconductor device is mounted, and wherein the substrate includes: an internal ground electrode, formed in the one side of the substrate, which is connected to the semiconductor device; two external ground electrodes, located at the opposite side of the substrate opposite to the one side of the substrate, which are electrically connected to the internal ground electrode; at least one sub-ground electrode, located between the two external ground electrodes, when seen in a plan view, and located at the opposite side of the substrate, which is electrically connected to the internal ground electrode; an internal input electrode, formed in the one side of the substrate, which is connected to the semiconductor device; and an internal output electrode, formed in the one side of the substrate, which is connected to the semiconductor device, and wherein the internal ground electrode is connected to the mounting substrate through the two external ground electrodes and the sub-ground electrode.

In still another embodiment, there is provided a method of mounting a semiconductor package, including: mounting the semiconductor package over a mounting substrate, wherein the semiconductor package includes: a semiconductor device; and a substrate over which the semiconductor device is mounted, and wherein the substrate includes: an internal ground electrode, formed in the one side of the substrate, which is connected to the semiconductor device; two external ground electrodes, located at the opposite side of the substrate opposite to the one side of the substrate, which are electrically connected to the internal ground electrode; at least one sub-ground electrode, located between the two external ground electrodes, when seen in a plan view, and located at the opposite side of the substrate, which is electrically connected to the internal ground electrode; an internal input electrode, formed in the one side of the substrate, which is connected to the semiconductor device; and an internal output electrode, formed in the one side of the substrate, which is connected to the semiconductor device, and wherein in the mounting the semiconductor package, the internal ground electrode is connected to the mounting substrate through the two external ground electrodes and the sub-ground electrode.

According to the invention, it is possible to make the inductance element value of the grounding path variable without changing the structure of the semiconductor package, and to control the amount of the positive feedback.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating the configuration of a semiconductor package according to a first embodiment.

FIGS. 2A and 2B are plan views illustrating the configuration of the semiconductor package shown in FIG. 1.

FIGS. 3A and 3B are cross-sectional views illustrating the configuration of a mounting structure of the semiconductor package shown in FIG. 1.

FIGS. 4A to 4G are cross-sectional views illustrating a method of manufacturing the semiconductor package shown in FIG. 1.

FIG. 5 is a cross-sectional view illustrating the configuration of the semiconductor package according to a second embodiment.

FIGS. 6A and 6B are plan views illustrating the configuration of the semiconductor package shown in FIG. 5.

FIGS. 7A and 7B are cross-sectional views illustrating the configuration of the mounting structure of the semiconductor package shown in FIG. 5.

FIGS. 8A to 8G are cross-sectional views illustrating the method of manufacturing the semiconductor package shown in FIG. 5.

FIG. 9 is a cross-sectional view illustrating the configuration of the semiconductor package according to a third embodiment.

FIGS. 10A and 10B are plan views illustrating the configuration of the semiconductor package shown in FIG. 9.

FIGS. 11A and 11B are cross-sectional views illustrating the configuration of the mounting structure of the semiconductor package shown in FIG. 9.

FIGS. 12A to 12D are cross-sectional views illustrating the method of manufacturing the semiconductor package shown in FIG. 9.

FIG. 13 is a cross-sectional view illustrating the configuration of the semiconductor package according to a fourth embodiment.

FIGS. 14A and 14B are plan views illustrating the configuration of the semiconductor package shown in FIG. 13.

FIG. 15 is a cross-sectional view illustrating the configuration of the semiconductor package according to a fifth embodiment.

FIGS. 16A and 16B are plan views illustrating the configuration of the semiconductor package shown in FIG. 15.

FIG. 17 is a cross-sectional view illustrating the configuration of the semiconductor package according to a sixth embodiment.

FIGS. 18A and 18B are plan views illustrating the configuration of the semiconductor package shown in FIG. 17.

FIG. 19 is a circuit diagram of a semiconductor device included in the semiconductor package shown in FIG. 17.

FIG. 20 is a cross-sectional view for explaining a problem of the invention.

FIG. 21 is a cross-sectional view for explaining the problem of the invention.

FIG. 22 is a cross-sectional view for explaining the problem of the invention.

FIG. 23 is a cross-sectional view for explaining the problem of the invention.

FIG. 24 is a circuit diagram for explaining the problem of the invention.

FIG. 25 is a correlation diagram for explaining an effect of the invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

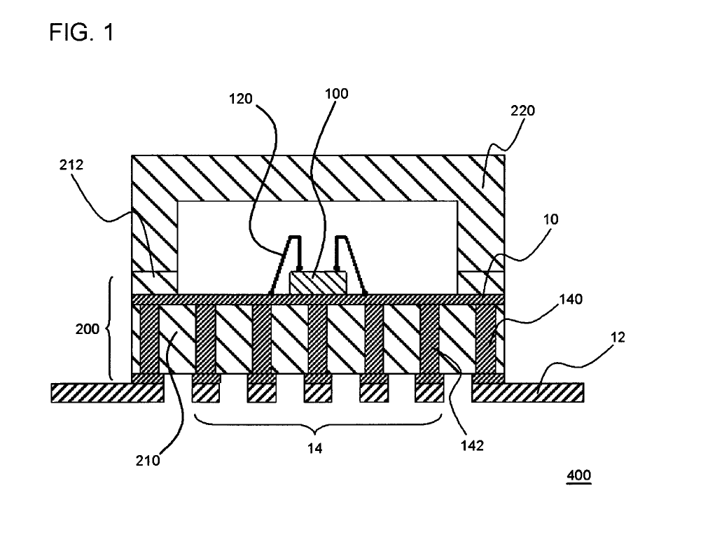

FIG. 1 is a cross-sectional view illustrating a semiconductor package 400 according to a first embodiment. The semiconductor package 400 according to the first embodiment includes a semiconductor device 100, a substrate 200, and a ceramic cap 220. The substrate 200, on which the semiconductor device 100 is mounted, includes a ceramic substrate 210, an internal ground electrode 10, two external ground electrodes 12, a plurality of sub-ground electrodes 14, and through holes 140, 142, 144 and 146.

The semiconductor device 100 has a field-effect transistor, and is sealed in an airtight manner by the substrate 200 and the ceramic cap 220. The inside of the semiconductor package 400 forms a hollow structure, and the semiconductor device 100 is not in contact with the ceramic cap 220.

The internal ground electrode 10 is formed in the one side of the substrate 200. In addition, the internal ground electrode 10, on which the semiconductor device 100 is mounted, is connected to a source of the field-effect transistor through a bonding wire 120. The external ground electrode 12 is located at the opposite side of the substrate 200 opposite to the one side, and is electrically connected to the internal ground electrode 10 through the through hole 140. The sub-ground electrodes 14 are located between two external ground electrodes 12 when seen in a plan view, are located at the opposite side of the substrate 200, and are electrically connected to the internal ground electrode 10 through the through hole 142. The connection surfaces of the external ground electrodes 12 and the sub-ground electrodes 14 to the outside stand in a line spaced from each other when seen in a plan view.

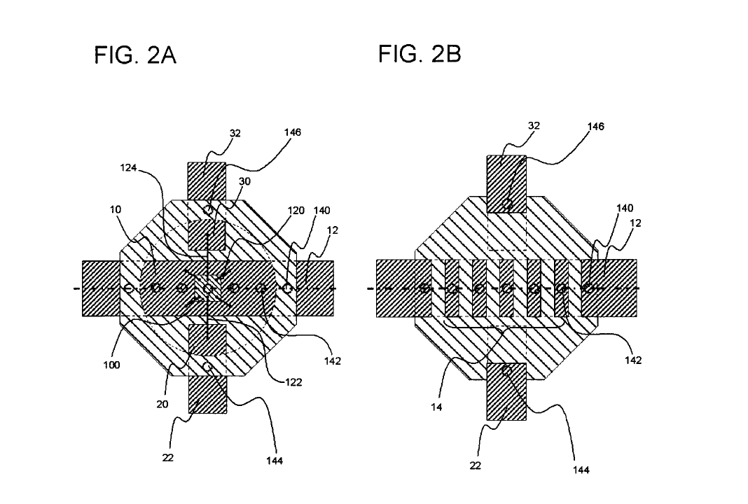

FIGS. 2A and 2B are plan views illustrating the configuration of the semiconductor package 400 shown in FIG. 1. FIG. 2A shows the inside of the semiconductor package 400 on the surface opposite to the mounting surface to the outside. FIG. 2B shows the mounting surface to the outside of the semiconductor package 400. The substrate 200 includes an internal input electrode 20 and an internal output electrode 30 on the one side thereof, and includes an external input electrode 22 and an external output electrode 32 on the opposite side thereof.

The sub-ground electrode 14 is located at a region overlapping the internal ground electrode 10 when seen in a plan view. In addition, the internal input electrode 20 and the internal output electrode 30 are located so as to face each other with the internal ground electrode 10 interposed between. The internal input electrode 20 is connected to a gate of the field-effect transistor through a bonding wire 122. The internal output electrode 30 is connected to a drain of the field-effect transistor through a bonding wire 124. The external input electrode 22 is electrically connected to the internal input electrode 20 through the through hole 144. The external output electrode 32 is electrically connected to the internal output electrode 30 through the through hole 146.

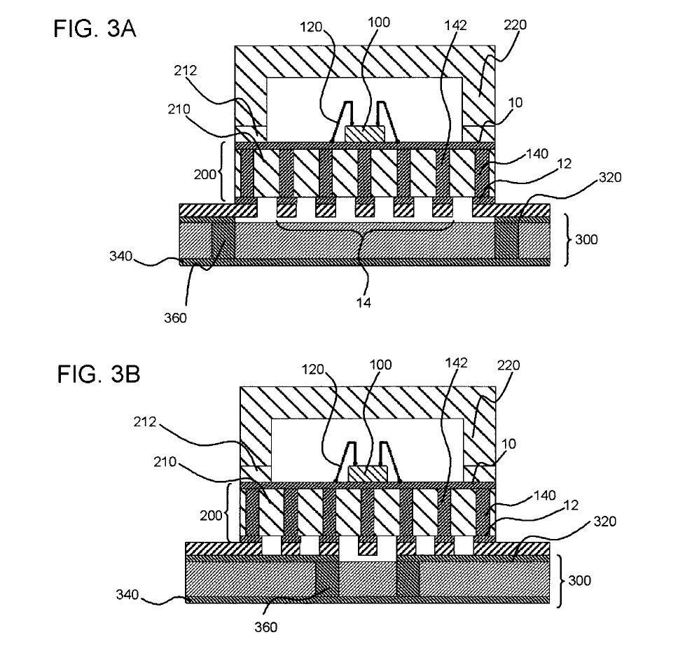

FIGS. 3A and 3B are cross-sectional views illustrating the configuration of a mounting structure of the semiconductor package 400 shown in FIG. 1. The mounting structure includes the semiconductor package 400 and a mounting substrate 300. The semiconductor package 400 is mounted on the one side of the mounting substrate 300. The mounting substrate 300 includes a ground interconnect 320 on the one side thereof, includes a back-side ground interconnect 340 on the opposite side opposite to the one side thereof, and includes a through hole 360 in the inside. The through hole 360 connects the back-side ground interconnect 340 with the end of the ground interconnect 320.

In FIGS. 3A and 3B, patterns of the ground interconnect 320 are different from each other. In FIG. 3A, the ground interconnect 320 is not formed in a part overlapping the semiconductor package 400, and only the external ground electrodes 12 are connected to the ground interconnect 320. In FIG. 3B, the end of the ground interconnect 320 extends to a part overlapping the semiconductor package 400, and the external ground electrodes 12 and the sub-ground electrodes 14 are connected to the ground interconnect 320.

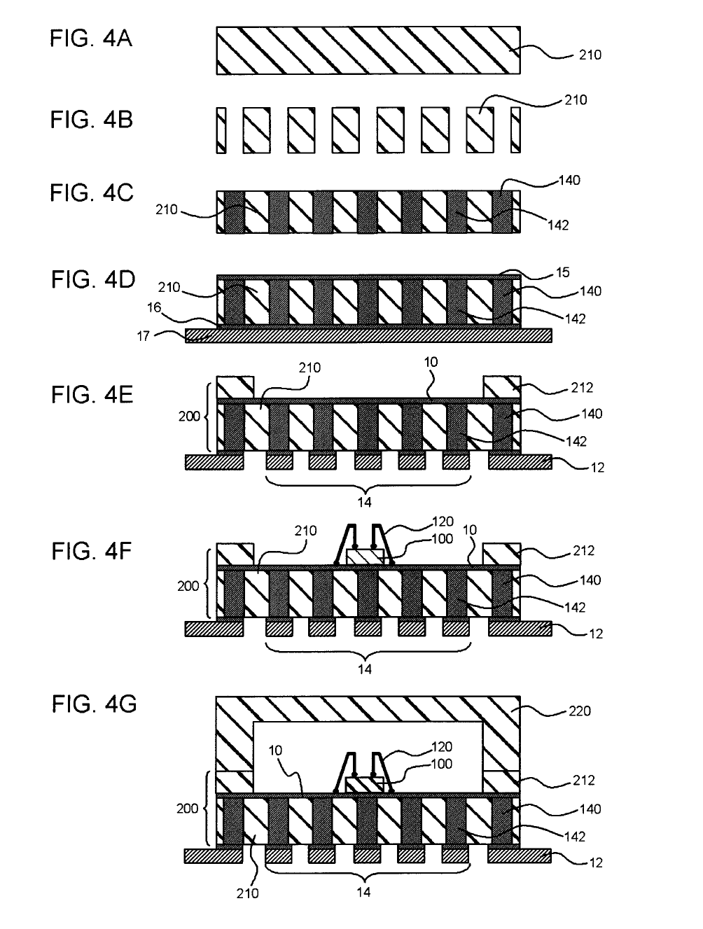

FIGS. 4A to 4G are cross-sectional views illustrating a method of manufacturing the semiconductor package 400 shown in FIG. 1. First, the through holes 140, 142, 144, and 146 are formed, as shown in FIG. 4B, in the insulating ceramic substrate 210 shown in FIG. 4A. Next, as shown in FIG. 4C, conducting layers are formed on at least sidewalls of the through holes 140, 142, 144, and 146. In addition, as shown in FIG. 4D, a conducting layer 15 is formed on the one side of the ceramic base 210, and a conducting layer 16 is formed on the opposite side opposite to the one side thereof. Further, a conducting sheet 17 is attached to the surface of the conducting layer 16. As shown in FIG. 4E, an electrode pattern is formed so that the internal ground electrode 10, the internal input electrode 20 (see FIGS. 2A and 2B) and the internal output electrode 30 (see FIGS. 2A and 2B) are formed on the one side of the ceramic substrate 210, and that the external ground electrode 12, the external input electrode 22 (see FIGS. 2A and 2B), the external output electrode 32 (see FIGS. 2A and 2B) and the sub-ground electrode 14 are formed on the opposite side of the ceramic substrate 210. Next, a ceramic member 212 is formed on the surface of the ceramic substrate 210 to form a pattern. Thereby, the substrate 200 is formed.

Next, as shown in FIG. 4F, the semiconductor device 100 is mounted on the internal ground electrode 10 of the substrate 200. Through the bonding wire 120, the internal ground electrode 10 is connected to the source of the field-effect transistor, the internal input electrode 20 is connected to the gate of the field-effect transistor, and the internal output electrode 30 is connect to the drain of the field-effect transistor. Further, as shown in FIG. 4G, the ceramic cap 220 is bonded to the substrate 200 so as to seal the semiconductor device 100 in an airtight manner. Thereby, the semiconductor package 400 is formed.

Thereafter, the mounting structure is formed by mounting the semiconductor package 400 on the mounting substrate 300. The semiconductor package 400 is connected to the ground interconnect 320 of the mounting substrate 300 through the external ground electrode 12, or through the external ground electrode 12 and the sub-ground electrode 14.

Next, the operations and effects of the first embodiment will be described with reference to FIGS. 3A and 3B, and FIGS. 20 to 25. When a portion of an output is returned to an input in an amplifier circuit, matching of both phases thereof brings a positive feedback, which results in an increase in the gain. On the other hand, in the case of the positive feedback, a stable coefficient or a noise figure of the amplifier circuit is degraded.

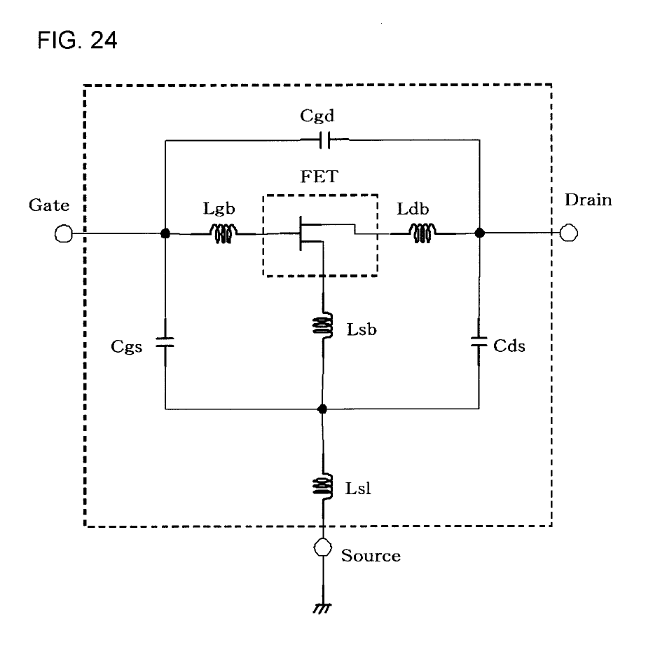

FIG. 24 is a circuit diagram illustrating an equivalent circuit of a field-effect transistor. As shown in FIG. 24, since a feedback path from an output to an input passes through the internal ground electrode 10 in its halfway point, the feedback path is grounded through an inductance element located between the internal ground electrode 10 and the external ground electrode 12. When the inductance element value of such a grounding path is brought close to zero, the feedback path is short-circuited along the way, and the amount of the positive feedback decreases. In addition, when the inductance element value of the grounding path is made larger, the amount of the positive feedback increases. Therefore, it is possible to set the gain, the stable coefficient and the noise figure to proper values by adjusting the inductance element value.

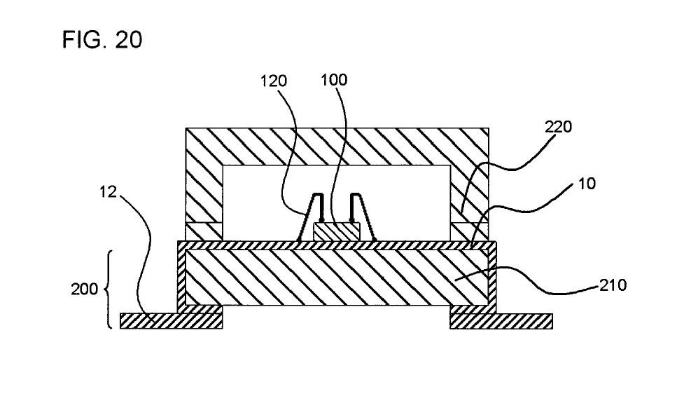

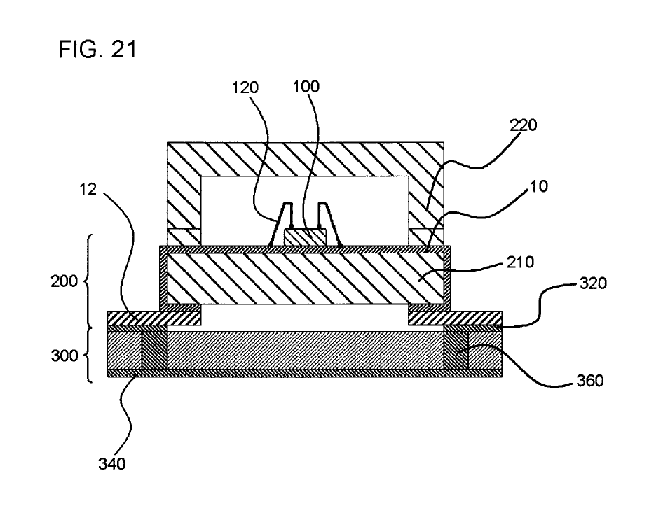

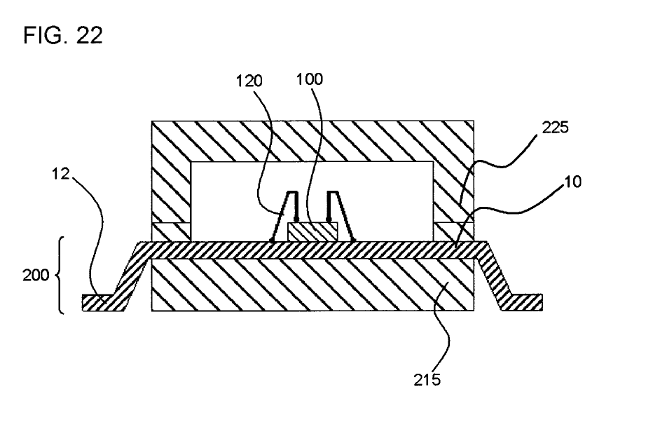

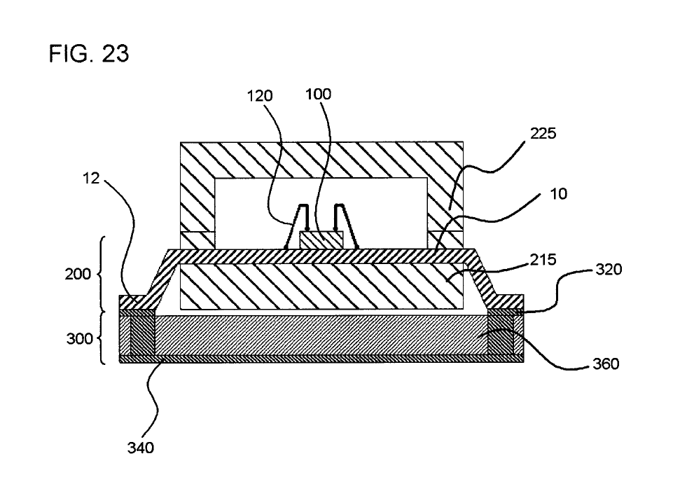

FIG. 20 and FIG. 22 are cross-sectional views illustrating the semiconductor package according to a comparative example. FIG. 21 and FIG. 23 are cross-sectional views illustrating the mounting structure according to the comparative example. According to the comparative example, the grounding path corresponds to only a path through the internal ground electrode and the external ground electrode. Therefore, redesign of the semiconductor package itself is required in order to change the inductance element value.

According to the embodiment, as shown in FIGS. 3A and 3B, two external ground electrodes 12 that connect the internal ground electrode 10 to the outside are provided in the substrate 200. In addition, a plurality of sub-ground electrodes 14 that connects the internal ground electrode 10 to the outside is provided between the two external ground electrodes 12. Thereby, the grounding path becomes a path through the sub-ground electrode 14 closer to the transistor than the external ground electrode 12. Therefore, the grounding path is shortened, and the inductance element value of the grounding path is reduced.

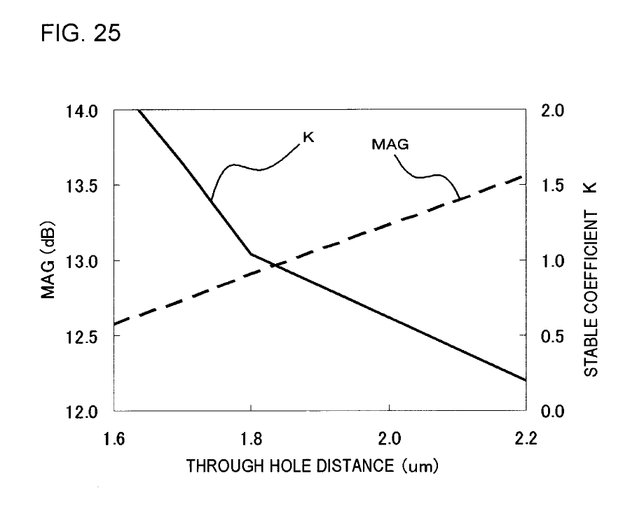

Further, it is possible to select the grounding path by changing the pattern of the ground interconnect 320 in the mounting substrate 300 and selecting the sub-ground electrode 14 to be connected. Thereby, the inductance element value of the grounding path can be made to be variable. FIG. 25 shows an example of the correlation between the distance of the through holes 360 in the mounting substrate 300 for determining the grounding path, and the gain and the stable coefficient. According to the embodiment, as shown in FIG. 25, it is possible to control the amount of the positive feedback by designing the mounting substrate 300 without changing the structure of the semiconductor package, and to perform the design of electronic components including the values of the gain, the stable coefficient and the noise figure.

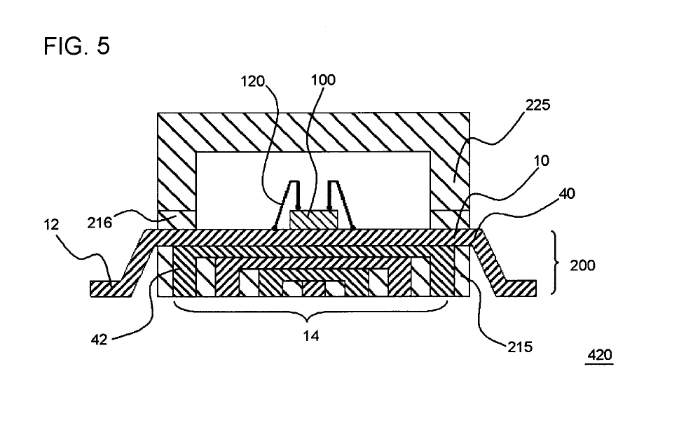

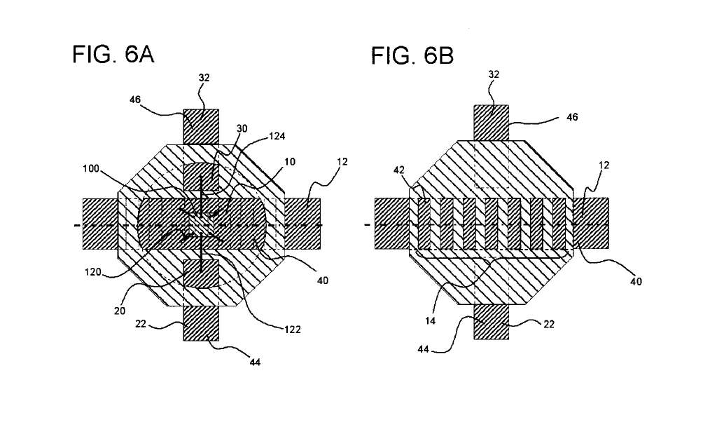

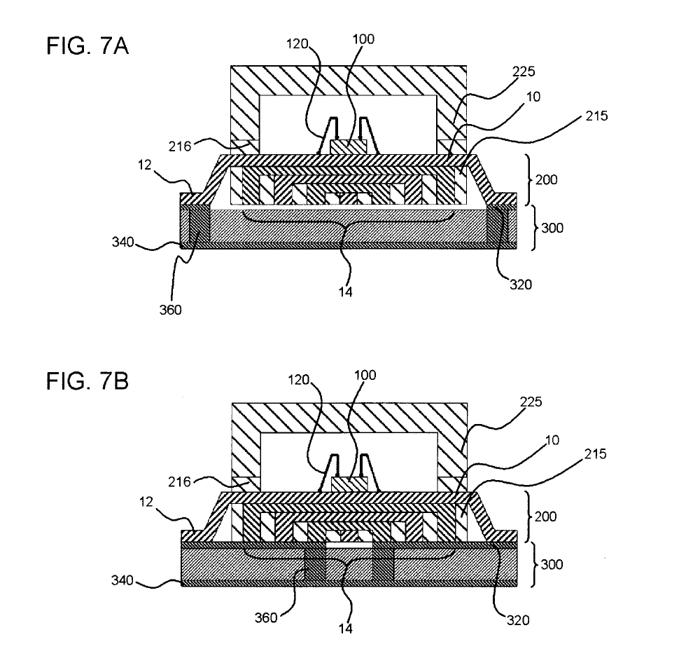

FIG. 5 is a cross-sectional view illustrating the configuration of a semiconductor package 420 according to a second embodiment, and corresponds to that of FIG. 1 according to the first embodiment. FIGS. 6A and 6B are plan views illustrating the configuration of the semiconductor package 420 shown in FIG. 5, and correspond to those of FIGS. 2A and 2B according to the first embodiment. FIGS. 7A and 7B are cross-sectional views illustrating the configuration of the mounting structure of the semiconductor package 420 shown in FIG. 5, and correspond to those of FIGS. 3A and 3B according to the first embodiment. The semiconductor package 420 and the mounting structure in the embodiment have the same configuration as those of the first embodiment except for the method of sealing the semiconductor device 100 and the structure of the substrate 200.

In the semiconductor package 420 according to the second embodiment, as shown in FIG. 5 and FIGS. 6A and 6B, the substrate 200 includes conductive plate-like members 40, 42, 44, and 46. The plate-like member 40 and a plurality of plate-like members 42 overlap each other. The plate-like member 40 forms the uppermost part at the one side of the substrate 200, and both ends thereof are bent at the opposite side of the substrate 200. Both ends of the plate-like member 40 form the external ground electrodes 12. At least a portion between both ends of the plate-like member 40 forms the internal ground electrode 10. Both ends of a plurality of plate-like members 42 are bent at the opposite side of the substrate 200, and both ends thereof form the sub-ground electrodes 14. Both ends of all plate-like members 42 are located on the same plane in the opposite side of the substrate 200.

The plate-like member 44 is configured such that the body portion thereof is located at the one side of the substrate 200, but one end thereof is bent toward the opposite side of the substrate 200. The plate-like member 44 is configured such that at least a portion of the section located at the one side of the substrate 200 forms the internal input electrode 20, and that the section located at the opposite side thereof forms the external input electrode 22. Similarly to the plate-like member 44, the plate-like member 46 is configured such that the body portion is located at the one side of the substrate 200, but one end thereof is bent toward the opposite side of the substrate 200. The plate-like member 46 is configured such that at least a portion of the section located at the one side of the substrate 200 forms the internal output electrode 30, and that the section located at the opposite side thereof forms the external output electrode 32. As shown in FIGS. 6A and 6B, the internal input electrode 20 and the internal output electrode 30 are located so as to face each other with the semiconductor device 100 interposed therebetween.

In the semiconductor package 420, as shown in FIG. 5, the semiconductor device 100 is sealed in an airtight manner by a resin cap 225 and the substrate 200. The inside of the semiconductor package 420 has a hollow structure, and the semiconductor device 100 is not in contact with the resin cap 225.

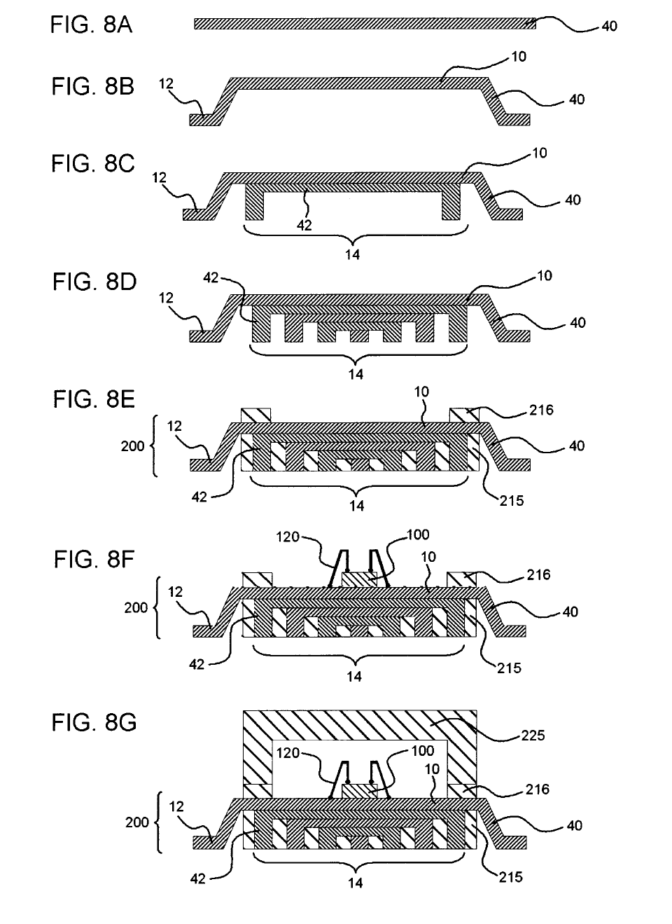

FIGS. 8A to 8G are cross-sectional views illustrating a method of manufacturing the semiconductor package 420 shown in FIG. 5. First, both ends of the plate-like member 40 shown in FIG. 8A are bent at the opposite side of the substrate 200 as shown in FIG. 8B, and then both ends thereof serve as the external ground electrode 12, and at least a portion between both ends thereof serves as the internal ground electrode 10. Next, as shown in FIGS. 8C and 8D, a plurality of plate-like members 42 of which both ends are bent at the opposite side of the substrate 200 is sequentially compressed between the external ground electrodes 12 to form a plurality of sub-ground electrodes 14. As a plurality of plate-like members 42 becomes closer to the opposite side of the substrate 200, the length thereof becomes shorter. Thereby, both ends of all plate-like members 42 are located on the same plane in the opposite side of the substrate 200.

Further, one end of the plate-like member 44 is bent, and then at least a portion of the section located at the one side of the substrate 200 serves as the internal input electrode 20, and the section located at the opposite side thereof serves as the external input electrode 22 (not shown). Similarly, one end of the plate-like member 46 is bent, and then at least a portion of the section located at the one side of the substrate 200 serves as the internal output electrode 30, and the section located at the opposite side thereof serves as the external output electrode 32 (not shown). As shown in FIG. 8E, a resin 215 is molded so as to fill spaces among a plurality of plate-like members 42 and the peripheries thereof at the opposite side of the substrate 200. In addition, a resin 216 is molded so as to surround the circumference of the semiconductor device 100 at the one side of the substrate 200. The resins 215 and 216 are formed by the same process. Thereby, the substrate 200 is formed.

Thereafter, as shown in FIG. 8F, the semiconductor device 100 is mounted on the internal ground electrode 10. Further, through the bonding wire 120, the internal ground electrode 10 is connected to the source of the field-effect transistor, the internal input electrode 20 is connected to the gate of the field-effect transistor, and the internal output electrode 30 is connected to the drain of the field-effect transistor. As shown in FIG. 8G, the resin cap 225 is bonded to the substrate 200 so as to seal the semiconductor device 100 in an airtight manner. Thereby, the semiconductor package 420 is formed.

Even in the embodiment, as shown in FIGS. 7A and 7B, two external ground electrodes 12 that connect the internal ground electrode 10 to the outside are provided in the substrate 200. In addition, a plurality of sub-ground electrodes 14 that connects the internal ground electrode 10 to the outside is provided between the two external ground electrodes 12. Therefore, it is possible to obtain the same effect as that of the first embodiment.

Moreover, in the embodiment, the semiconductor package 420 is sealed in an airtight manner by the resin cap 225. Thereby, the semiconductor package can be manufactured at lower cost compared to using a ceramic package as shown in the first embodiment. Further, the substrate 200 in the embodiment has a higher mechanical processing accuracy than the substrate 200 in the first embodiment. Therefore, it is possible to make the variation of the electrical characteristics smaller than that of the first embodiment.

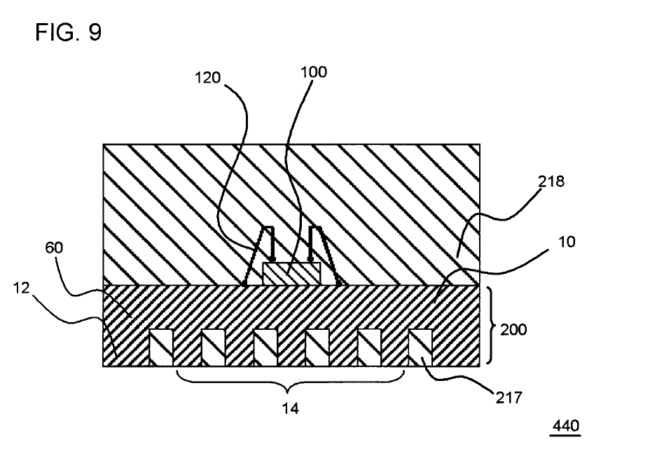

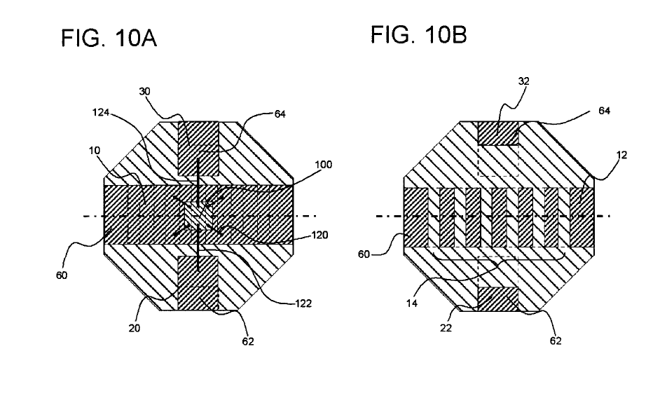

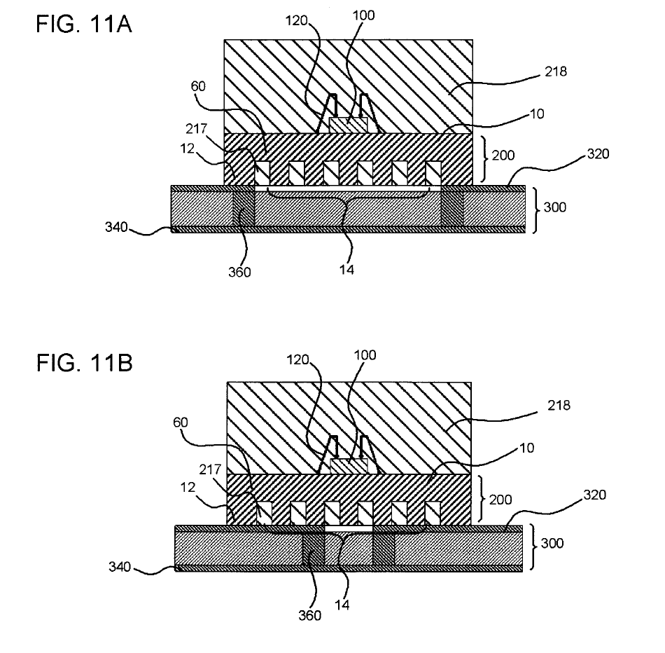

FIG. 9 is a cross-sectional view illustrating the configuration of a semiconductor package 440 according to a third embodiment, and corresponds to that of FIG. 1 according to the first embodiment. FIGS. 10A and 10B are plan views illustrating the configuration of the semiconductor package 440 shown in FIG. 9, and correspond to those of FIGS. 2A and 2B according to the first embodiment. FIGS. 11A and 11B are cross-sectional views illustrating the configuration of the mounting structure of the semiconductor package 440 shown in FIG. 9, and correspond to those of FIGS. 3A and 3B according to the first embodiment. The semiconductor package 440 and the mounting structure in the embodiment have the same configuration as those of the first embodiment except for the method of sealing the semiconductor device 100 and the structure of the substrate 200.

In the semiconductor package 440 according to the third embodiment, as shown in FIG. 9 and FIGS. 10A and 10B, the substrate 200 includes metal members 60, 62, and 64. In the opposite side of the substrate 200, a plurality of grooves is formed in the metal member 60. Thereby, in the opposite side of the substrate 200, a plurality of convex portions is formed in the metal member 60. At least a portion of the section located at the surface of the substrate 200, of the metal member 60, forms the internal ground electrode 10. In addition, among the convex portions formed in the metal member 60, the convex portions located at both ends thereof form the external ground electrodes 12, and the convex portions except for the convex portions at both ends thereof form the sub-ground electrodes 14.

In addition, as shown in FIGS. 10A and 10B, the metal member 62 and the metal member 64 are located so as to face each other with the metal member 60 interposed therebetween. The metal member 62 is configured such that the inward portion thereof is cut in the opposite side of the substrate 200, at least a portion of the section located at the surface of the substrate 200 forms the internal input electrode 20, and that the section located at the opposite side thereof forms the external input electrode 22. Similarly, the metal member 64 is configured such that the inward portion thereof is cut in the opposite side of the substrate 200, at least a portion of the section located at the surface of the substrate 200 forms the internal output electrode 30, and that the section located at the opposite side thereof forms the external output electrode 32. The semiconductor device 100 is sealed by a resin 218.

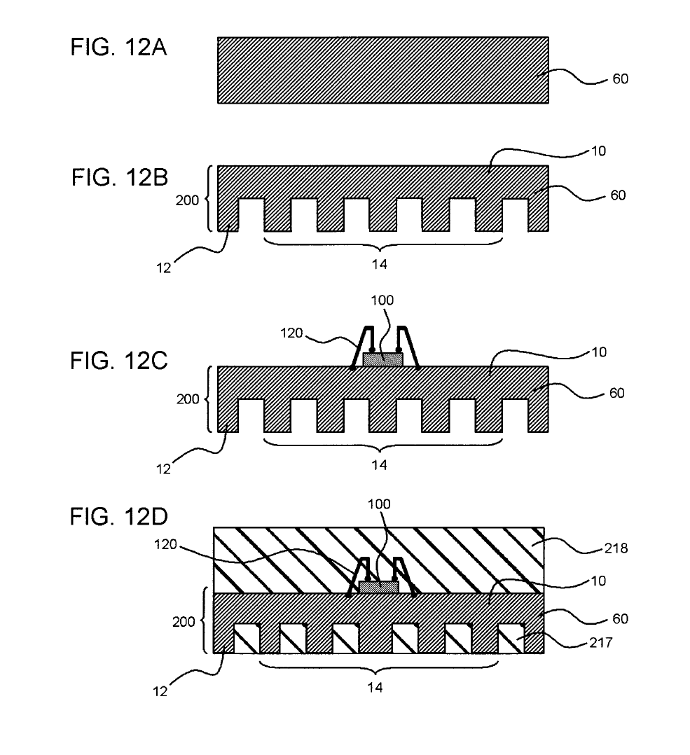

FIGS. 12A to 12D are cross-sectional views illustrating a method of manufacturing the semiconductor package 440 shown in FIG. 9. First, a metallic base material is separated, and the metal member 60, the metal member 62, and the metal member 64 are formed (not shown). Next, in the opposite side of the substrate 200, as shown in FIG. 12B, a plurality of grooves is formed in the metal member 60 shown in FIG. 12A. Thereby, the internal ground electrode 10 is formed in at least a portion of the section located at the one side of the substrate 200, of the metal member 60, and the external ground electrodes 12 and the sub-ground electrodes 14 are formed in the section located at the opposite side of the substrate 200, of the metal member 60. In addition, the inward portion of the metal member 62 is cut in the opposite side of the substrate 200 (not shown). The internal input electrode 20 is formed in at least a portion of the section located at the one side of the substrate 200, of the metal member 62, and the external input electrode 22 is formed in the section located at the opposite side of the substrate 200, of the metal member 62. Similarly, the inward portion of the metal member 64 is cut in the opposite side of the substrate 200 (not shown). The internal output electrode 30 is formed in at least a portion of the section located at the surface of the substrate 200, of the metal member 64, and the external output electrode 32 is formed in the section located at the opposite side of the substrate 200, of the metal member 64. Thereby, the substrate 200 is formed.

Thereafter, as shown in FIG. 12C, the semiconductor device 100 is mounted on the internal ground electrode 10, and the internal ground electrode 10 is connected to the source of the field-effect transistor through the bonding wire 120. Similarly, the internal input electrode 20 is connected to the gate of the field-effect transistor, and the internal output electrode 30 is connected to the drain of the field-effect transistor (not shown). As shown in FIG. 12D, a resin 217 is molded so as to fill spaces among the grooves of the metal member 60 in the opposite side of the substrate 200. In addition, the semiconductor device 100 is sealed by the resin 218 in the surface of the substrate 200. This is divided individually, and thus the semiconductor package 440 is formed.

Even in the embodiment, as shown in FIGS. 11A and 11B, two external ground electrodes 12 that connect the internal ground electrode 10 to the outside are provided in the substrate 200. In addition, a plurality of sub-ground electrodes 14 that connects the internal ground electrode 10 to the outside is provided between the two external ground electrodes 12. Therefore, it is possible to obtain the same effect as that of the first embodiment.

Moreover, in the embodiment, the manufacturing process thereof is simpler than those of the first and second embodiments. Therefore, it is possible to manufacture the semiconductor package 440 at lower cost compared to the first and second embodiments.

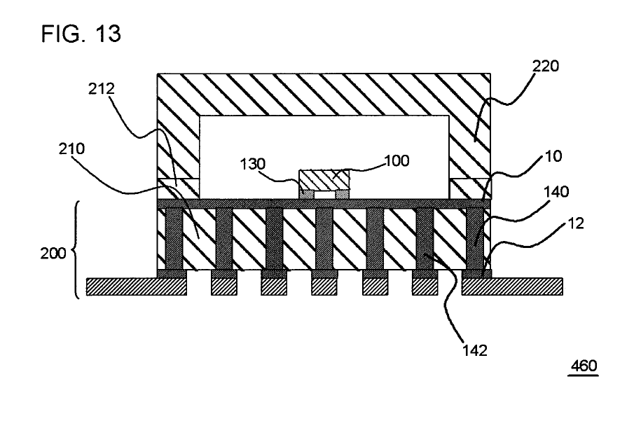

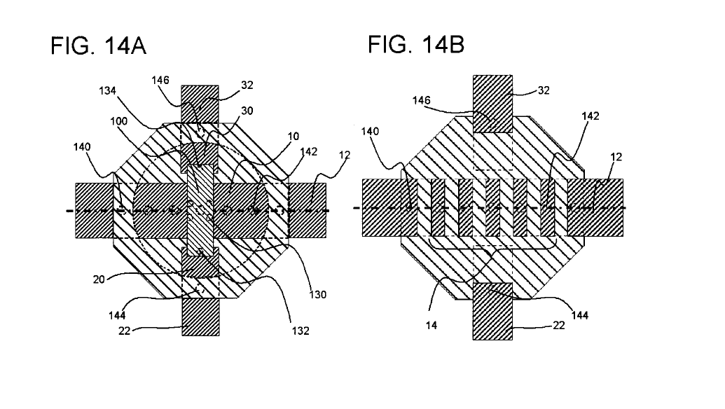

FIG. 13 is a cross-sectional view illustrating a semiconductor package 460 according to a fourth embodiment, and corresponds to that of FIG. 1 according to the first embodiment. FIGS. 14A and 14B are plan views illustrating the semiconductor package 460 shown in FIG. 13, and correspond to those of FIGS. 2A and 2B according to the first embodiment. The semiconductor package 460 in the embodiment has the same configuration as that of the semiconductor package 400 according to the first embodiment except that the semiconductor device 100 is mounted on the substrate 200 through the flip-chip connection.

Specifically, the semiconductor device 100 is mounted on the substrate 200 through bumps 130, 132 and 134 so that the active face thereof is opposite to the substrate 200. The internal ground electrode 10 is connected to the semiconductor device 100 through the bump 130. The internal input electrode 20 is connected to the semiconductor device 100 through the bump 132. The internal output electrode 30 is connected to the semiconductor device 100 through the bump 134.

Even in the embodiment, as shown in FIG. 13, two external ground electrodes 12 that connect the internal ground electrode 10 to the outside are added to the substrate 200, and a plurality of sub-ground electrodes 14 that connects the internal ground electrode 10 to the outside is provided between the two external ground electrodes 12. Therefore, it is possible to obtain the same effect as that of the first embodiment.

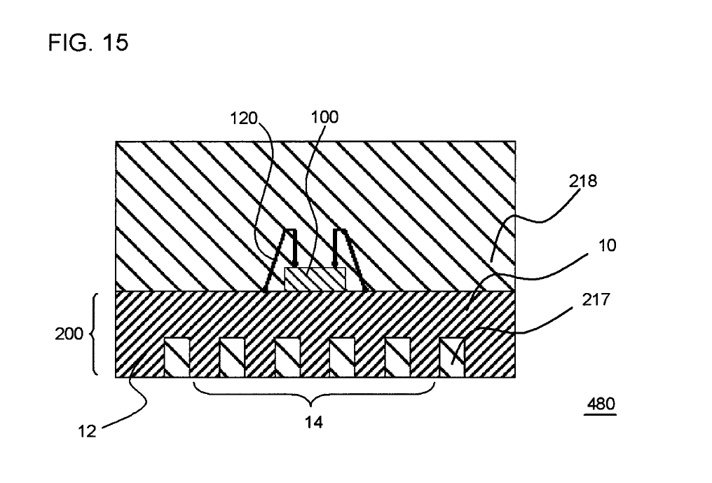

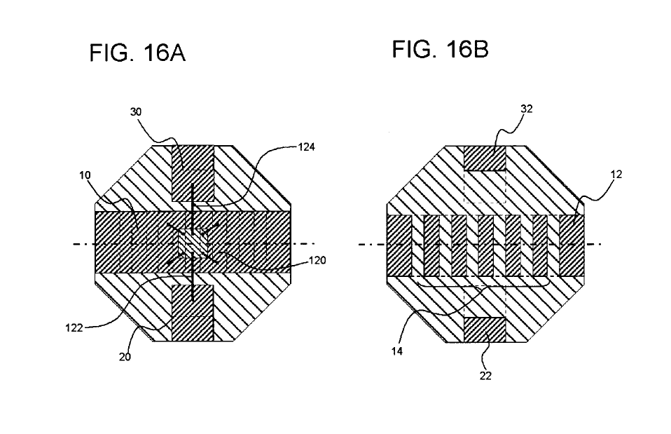

FIG. 15 is a cross-sectional view illustrating a semiconductor package 480 according to a fifth embodiment, and corresponds to that of FIG. 9 according to the third embodiment. FIGS. 16A and 16B are plan views illustrating the semiconductor package 480 shown in FIG. 15, and correspond to those of FIGS. 10A and 10B according to the third embodiment. The semiconductor package 480 in the embodiment has the same configuration as that of the semiconductor package 440 according to the third embodiment except for the configuration of the semiconductor device 100.

The semiconductor device 100 according to the embodiment has a bipolar transistor. In the semiconductor package 480 according to the embodiment, the internal ground electrode 10 is connected to an emitter of the bipolar transistor, the internal input electrode 20 is connected to a base of the bipolar transistor, and the internal output electrode 30 is connected to a collector of the bipolar transistor.

Even in the embodiment, as shown in FIG. 15, the two external ground electrodes 12 that connect the internal ground electrode 10 to the outside are provided in the substrate 200. In addition, a plurality of sub-ground electrodes 14 that connects the internal ground electrode 10 to the outside is provided between the two external ground electrodes 12. In addition, a method of manufacturing the semiconductor package 480 is the same as the method of manufacturing the semiconductor package 440 according to the third embodiment. Therefore, it is possible to obtain the same effect as that of the third embodiment.

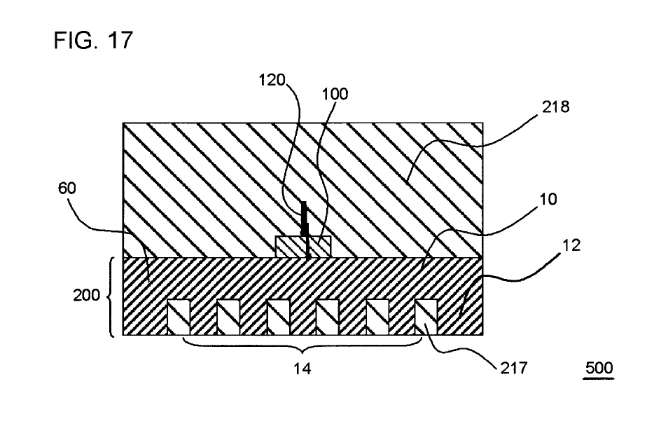

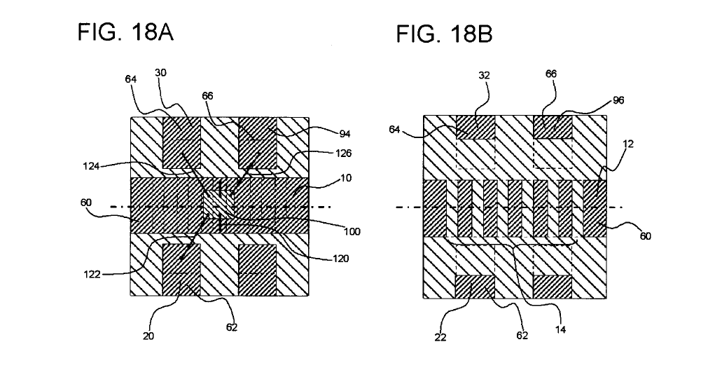

FIG. 17 is a cross-sectional view illustrating a semiconductor package 500 according to a sixth embodiment, and corresponds to that of FIG. 9 according to the third embodiment. FIGS. 18A and 18B are plan views illustrating the semiconductor package 500 shown in FIG. 17, and correspond to those of FIGS. 10A and 10B according to the third embodiment. The semiconductor package 500 in the embodiment has the same configuration as that of the semiconductor package 440 according to the third embodiment except for the configurations of the semiconductor device 100 and the electrodes.

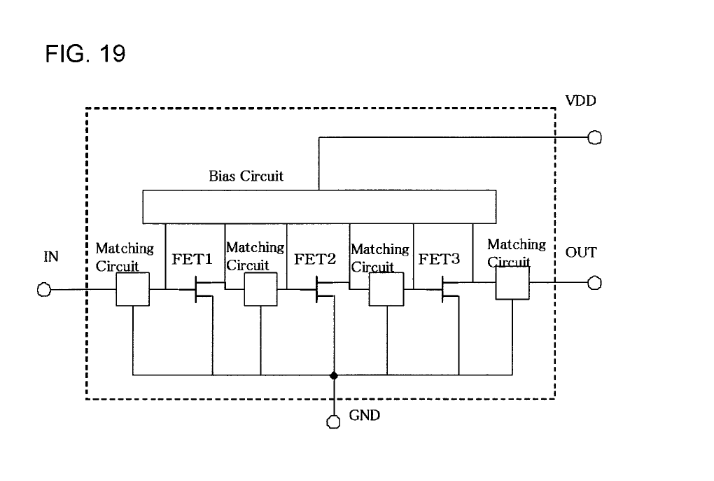

The semiconductor device 100 according to the embodiment has an integrated circuit. FIG. 19 is a circuit diagram illustrating an equivalent circuit of the integrated circuit according to the embodiment. As shown in FIGS. 18A and 18B, the semiconductor package 500 according to the embodiment has an internal VDD electrode 94 and an external VDD electrode 96 for a bias source. A metal member 66 is located at the side opposite to the metal member 62 with reference to the metal member 60. The metal member 66 is configured such that the inward portion thereof is cut in the opposite side of the substrate 200, at least a portion of the section located at the one side of the substrate 200 forms the internal VDD electrode 94, and that the section located at the opposite side thereof forms the external VDD electrode 96. The internal VDD electrode 94 is connected to the semiconductor device 100 through a bonding wire 126.

Even in the embodiment, as shown in FIG. 17, the two external ground electrodes 12 that connect the internal ground electrode 10 to the outside are provided in the substrate 200. In addition, a plurality of sub-ground electrodes 14 that connects the internal ground electrode 10 to the outside is provided between the two external ground electrodes 12. In addition, a method of manufacturing the semiconductor package 500 is the same as the method of manufacturing the semiconductor package 440 according to the third embodiment, except that the metal member 66 is formed by the same process as those of the internal ground electrode 10, the internal input electrode 20, and the internal output electrode 30 in the manufacturing process of the substrate 200. The metal member 66 is formed and processed simultaneously with the metal members 60, 62 and 64. Therefore, it is possible to obtain the same effect as that of the third embodiment.

As described above, although the embodiments of the invention have been set forth with reference to the drawings, they are merely illustrative of the invention, and various configurations other than those stated above can be adopted.

It is apparent that the present invention is not limited to the above embodiment, and may be modified and changed without departing from the scope and spirit of the invention.

What is claimed is:

1. A semiconductor package comprising:
a semiconductor device; and
a substrate over which said semiconductor device is mounted,
wherein said substrate includes:
an internal ground electrode, formed in the one side of said substrate, which is connected to said semiconductor device;
two external ground electrodes, located at the opposite side of said substrate opposite to said one side, which are electrically connected to said internal ground electrode;
at least one sub-ground electrode, located between said two external ground electrodes, when seen in a plan view, and located at said opposite side of said substrate, which is electrically connected to said internal ground electrode;
an internal input electrode, formed in said one side of said substrate, which is connected to said semiconductor device; and
an internal output electrode, formed in said one side of said substrate, which is connected to said semiconductor device.

2. The semiconductor package as set forth in claim 1,
wherein said substrate has a plurality of said sub-ground electrodes, and the connection surfaces of said two external ground electrodes and said plurality of sub-ground electrodes to the outside stand in a line spaced from each other in said opposite side of said substrate.

3. The semiconductor package as set forth in claim 1, further comprising:
a first through hole that connects said internal ground electrode with said external ground electrode; and
a second through hole that connects said internal ground electrode with said sub-ground electrode.

4. The semiconductor package as set forth in claim 1,
wherein said substrate has a plurality of conductive plate-like members overlapped with each other,
a first plate-like member of said plurality of plate-like members is configured such that it form the uppermost part at said one side of said substrate, both ends thereof are bent at said opposite side of the substrate, said both ends form said external ground electrodes, and that at least a portion between said both ends forms said internal ground electrode, and
a second plate-like member of said plurality of plate-like members is configured such that both ends thereof are bent at said opposite side of the substrate, and that said both ends form said sub-ground electrodes.

5. The semiconductor package as set forth in claim 1,
wherein said substrate has a plurality of grooves, and convex portions located between said grooves at said opposite side,
at least a portion of a section overlapping a region in which said plurality of grooves is formed, in said one side of said substrate, forms said internal ground electrode,
said convex portions of both ends formed in said opposite side of said substrate form said external ground electrodes, and
said convex portions except said convex portions of both ends formed in said opposite side of said substrate form said sub-ground electrodes.

6. The semiconductor package as set forth in claim 1,
wherein said semiconductor device has a field-effect transistor, said internal ground electrode is connected to a source of said field-effect transistor, said internal input electrode is connected to a gate of said field-effect transistor, and said internal output electrode is connected to a drain of said field-effect transistor.

7. The semiconductor package as set forth in claim 1,
wherein said semiconductor device has a bipolar transistor, said internal ground electrode is connected to an emitter of said bipolar transistor, said internal input electrode is connected to a base of said bipolar transistor, and said internal output electrode is connected to a collector of said bipolar transistor.

8. A substrate comprising:
an internal ground electrode formed in the one side of said substrate;
two external ground electrodes, located at the opposite side of said substrate opposite to said one side, which are electrically connected to said internal ground electrode;
at least one sub-ground electrode, located between said two external ground electrodes, when seen in a plan view, and located at the opposite side of said substrate, which is electrically connected to said internal ground electrode;
an internal input electrode formed in said one side of said substrate; and
an internal output electrode formed in said one side of said substrate.

9. An electronic component comprising:
a mounting substrate; and
a semiconductor package mounted over said mounting substrate,
wherein said semiconductor package includes:
a semiconductor device; and
a substrate over which said semiconductor device is mounted, and
wherein said substrate includes:
an internal ground electrode, formed in the one side of said substrate, which is connected to said semiconductor device;
two external ground electrodes, located at the opposite side of said substrate opposite to said one side, which are electrically connected to said internal ground electrode;
at least one sub-ground electrode, located between said two external ground electrodes, when seen in a plan view, and located at said opposite side of said substrate, which is electrically connected to said internal ground electrode;
an internal input electrode, formed in said one side of said substrate, which is connected to said semiconductor device; and
an internal output electrode, formed in said one side of said substrate, which is connected to said semiconductor device, and
wherein said internal ground electrode is connected to said mounting substrate through said two external ground electrodes and said sub-ground electrode.

10. A method of mounting a semiconductor package, comprising:
mounting the semiconductor package over a mounting substrate,
wherein said semiconductor package includes:
a semiconductor device; and
a substrate over which said semiconductor device is mounted, and
wherein said substrate includes:
an internal ground electrode, formed in the one side of said substrate, which is connected to said semiconductor device;
two external ground electrodes, located at the opposite side of said substrate opposite to said one side, which are electrically connected to said internal ground electrode;
at least one sub-ground electrode, located between said two external ground electrodes, when seen in a plan view, and located at said opposite side of said substrate, which is electrically connected to said internal ground electrode;
an internal input electrode, formed in said one side of said substrate, which is connected to said semiconductor device; and
an internal output electrode, formed in said one side of said substrate, which is connected to said semiconductor device, and
wherein in said mounting the semiconductor package, said internal ground electrode is connected to the mounting substrate through said two external ground electrodes and said sub-ground electrode.
